(19) United States
(12) Patent Application Publication
(10) Pub. No.: US 2026/0269785 A1
(43) Pub. Date: Sep. 10, 2026

(54) VOLTAGE STANDING WAVE RATIO IMMUNITY IN A POWER MANAGEMENT CIRCUIT

(71) Applicant: Qorvo US, Inc., Greensboro, NC (US)

(72) Inventors: Nadim Khlat, Ceret (FR); James M. Retz, Cedar Rapids, IA (US); Toshiaki Moriuchi, San Jose, CA (US); Hwiseob Lee, Cupertino, CA (US)

(21) Appl. No.: 19/538,487

(22) Filed: Feb. 12, 2026

Related U.S. Application Data
(60) Provisional application No. 63/767,658, filed on Mar. 6, 2025.
(60) Provisional application No. 63/767,654, filed on Mar. 6, 2025.

(51) Int. Cl. H03F 1/02; H03F 1/56; H03F 3/24

(52) U.S. Cl. CPC H03F 1/02; H03F 1/565; H03F 3/24; H03F 2200/102; H03F 2200/192; H03F 2200/204; H03F 2200/336; H03F 2200/451

(57) ABSTRACT

Improving voltage standing wave ratio (VSWR) immunity in a power management circuit is disclosed. Herein, a power amplifier circuit includes an input hybrid coupler, a pair of power amplifiers, and an output hybrid coupler. The input hybrid coupler splits a radio frequency (RF) signal into an in-phase signal and a quadrature signal. One power amplifier is always active to amplify the quadrature signal, whereas another power amplifier is only active to amplify the in-phase signal when an instantaneous power level of the RF signal is above a threshold. The output hybrid coupler outputs the amplified RF signal and performs load modulation based on the instantaneous power level of the RF signal. Herein, the power amplifier circuit can dynamically change termination impedance of the output hybrid coupler based on the instantaneous power level and/or modulation bandwidth of the RF signal to help improve VSWR immunity across a wide power range.

### RELATED APPLICATIONS

This application claims the benefit of U.S. provisional patent application serial number 63/767,654, filed on March 6, 2025, and U.S. provisional patent application serial number 63/767,658, filed on March 6, 2025, the disclosures of which are hereby incorporated herein by reference in their entireties.

### FIELD OF THE DISCLOSURE

The present disclosure is related to improving voltage standing wave ratio (VSWR) immunity in a power management circuit.

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

The redefined user experience requires higher data rates offered by advanced wireless communication technologies such as fifth-generation new-radio (5G-NR). To achieve higher data rates, a mobile communication device is required to amplify a transmission signal to a desired power level to help overcome potential propagation losses and/or interferences. As such, the mobile communication device typically includes a transceiver circuit, a power amplifier circuit, and a power management circuit. Specifically, the transceiver circuit modulates the transmission signal to an intended transmission frequency, the power amplifier circuit amplifies the transmission signal to the desired power level, and the power management circuit supplies an envelope tracking (ET) voltage to the power amplifier circuit. Understandably, to achieve the best possible efficiency and performance, the power management circuit must adapt the ET voltage in accordance with a modulation bandwidth of the transmission signal.

### SUMMARY

Embodiments of the disclosure relate to improving voltage standing wave ratio (VSWR) immunity in a power management circuit. Herein, a power amplifier circuit includes an input hybrid coupler, a pair of power amplifiers, and an output hybrid coupler. The input hybrid coupler splits a radio frequency (RF) signal into an in-phase signal and a quadrature signal. One power amplifier is always active to amplify the quadrature signal based on a supply voltage, whereas another power amplifier is only active to amplify the in-phase signal based on the supply voltage when an instantaneous power level of the RF signal is above a first threshold. The output hybrid coupler combines the amplified quadrature signal and the amplified in-phase signal to thereby output the amplified RF signal. To help reduce a dynamic range of the supply voltage, the output hybrid coupler performs load modulation when the instantaneous power level of the RF signal is above the first threshold but below a second threshold and presents a fixed load impedance when the instantaneous power level is above the second threshold. In embodiments disclosed herein, the power amplifier circuit is configured to dynamically change a termination impedance of the output hybrid coupler based on the instantaneous power level and/or modulation bandwidth of the RF signal. As a result, it is possible to improve VSWR immunity (e.g., reduce reverse intermodulation) across a wide power range of the RF signal.

In one aspect, a power management circuit is provided. The power management circuit includes a power amplifier circuit. The power amplifier circuit includes an input hybrid coupler. The input hybrid coupler is configured to split an RF signal into an in-phase signal and a quadrature signal. The power amplifier circuit also includes a first power amplifier. The first power amplifier is always activated to amplify the quadrature signal based on a supply voltage. The power amplifier circuit also includes a second power amplifier. The second power amplifier is activated only when an instantaneous power level of the RF signal is higher than a first power threshold to amplify the in-phase signal based on the supply voltage. The power amplifier circuit also includes an output hybrid coupler. The output hybrid coupler includes an isolation port. The isolation port is terminated by a termination impedance. The output hybrid coupler is configured to output the amplified RF signal based on the amplified quadrature signal and the amplified in-phase signal. The power amplifier circuit also includes an isolation circuit. The isolation circuit is coupled to the isolation port. The isolation circuit is configured to present the termination impedance at the isolation port. The power amplifier circuit also includes a control circuit. The control circuit is configured to control the isolation circuit to adapt the termination impedance based on any of the instantaneous power level and a modulation bandwidth of the RF signal.

In another aspect, a wireless device is provided. The wireless device includes a power management circuit. The power management circuit includes a power amplifier circuit. The power amplifier circuit includes an input hybrid coupler. The input hybrid coupler is configured to split an RF signal into an in-phase signal and a quadrature signal. The power amplifier circuit also includes a first power amplifier. The first power amplifier is always activated to amplify the quadrature signal based on a supply voltage. The power amplifier circuit also includes a second power amplifier. The second power amplifier is activated only when an instantaneous power level of the RF signal is higher than a first power threshold to amplify the in-phase signal based on the supply voltage. The power amplifier circuit also includes an output hybrid coupler. The output hybrid coupler includes an isolation port. The isolation port is terminated by a termination impedance. The output hybrid coupler is configured to output the amplified RF signal based on the amplified quadrature signal and the amplified in-phase signal. The power amplifier circuit also includes an isolation circuit. The isolation circuit is coupled to the isolation port. The isolation circuit is configured to present the termination impedance at the isolation port. The power amplifier circuit also includes a control circuit. The control circuit is configured to control the isolation circuit to adapt the termination impedance based on any of the instantaneous power level and a modulation bandwidth of the RF signal.

In another aspect, a method for improving VSWR immunity in a power management circuit is provided. The method includes splitting, using an input hybrid coupler, an RF signal into an in-phase signal and a quadrature signal. The method also includes always activating a first power amplifier to amplify the quadrature signal based on a supply voltage. The method also includes activating a second power amplifier only when an instantaneous power level of the RF signal is higher than a first power threshold to amplify the in-phase signal based on the supply voltage. The method also includes combining, using an output hybrid coupler, the amplified quadrature signal with the amplified in-phase signal to thereby output the amplified RF signal. The method also includes presenting a termination impedance at an isolation port of the output hybrid coupler. The method also includes adapting the termination impedance based on any of the instantaneous power level and a modulation bandwidth of the RF signal.

In another aspect, a power management circuit is provided. The power management circuit includes a power amplifier circuit. The power amplifier circuit includes an input hybrid coupler. The input hybrid coupler is configured to split an RF signal into an in-phase signal and a quadrature signal. The power amplifier circuit also includes a first power amplifier. The first power amplifier is always activated to amplify the quadrature signal based on a supply voltage. The power amplifier circuit also includes a second power amplifier. The second power amplifier is activated only when an instantaneous power level of the RF signal is higher than a first power threshold to amplify the in-phase signal based on the supply voltage. The power amplifier circuit also includes an output hybrid coupler. The output hybrid coupler has an isolation port terminated by a termination impedance. The output hybrid coupler is configured to output the amplified RF signal based on the amplified quadrature signal and the amplified in-phase signal. The power amplifier circuit also includes a control circuit. The control circuit is configured to cause a termination resistance to be presented at the isolation port when the modulation bandwidth of the RF signal is lower than a bandwidth threshold such that the power amplifier circuit can operate as a balanced power amplifier circuit. The control circuit is also configured to cause a termination reactance to be presented at the isolation port when the modulation bandwidth of the RF signal is higher than or equal to the bandwidth threshold such that the power amplifier circuit can operate based at least on load modulation.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is a schematic diagram of an exemplary power management circuit wherein an isolation circuit can be provided in a power amplifier circuit and configured according to embodiments of the present disclosure to adapt a termination impedance based on an instantaneous power level and/or modulation bandwidth of a radio frequency (RF) signal being amplified by the power amplifier circuit to help improve voltage standing wave ratio (VSWR) immunity of the power management circuit;

FIG. 2 is a graphic diagram illustrating an operating principle of the power amplifier circuit in FIG. 1;

FIG. 3A is a graphic diagram illustrating how the isolation circuit in FIG. 1 can dynamically adapt the termination impedance based on the instantaneous power level of the RF signal;

FIG. 3B is a graphic diagram illustrating how the isolation circuit in FIG. 1 can dynamically adapt the termination impedance based on the modulation bandwidth of the RF signal;

FIG. 3C is a flowchart illustrating how the power management circuit of FIG. 1 can generate a supply voltage for amplifying the RF signal at the power amplifier circuit based on the modulation bandwidth of the RF signal;

FIGS. 4A-4C are schematic diagrams illustrating the isolation circuit in FIG. 1 configured according to various embodiments of the present disclosure;

FIGS. 5A-5D are graphic diagrams providing exemplary illustrations of VSWR immunity improvement achieved by the power amplifier circuit in FIG. 1;

FIG. 6 is a schematic diagram of an exemplary communication device wherein the power management circuit of FIG. 1 can be provided; and

FIG. 7 is a flowchart of an exemplary process for improving VSWR immunity in the power management circuit of FIG. 1.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term "and/or" includes any and all combinations of one or more of the associated listed items.

It will be understood that when an element such as a layer, region, or substrate is referred to as being "on" or extending "onto" another element, it can be directly on or extend directly onto the other element or intervening elements may also be present. In contrast, when an element is referred to as being "directly on" or extending "directly onto" another element, there are no intervening elements present. Likewise, it will be understood that when an element such as a layer, region, or substrate is referred to as being "over" or extending "over" another element, it can be directly over or extend directly over the other element or intervening elements may also be present. In contrast, when an element is referred to as being "directly over" or extending "directly over" another element, there are no intervening elements present. It will also be understood that when an element is referred to as being "connected" or "coupled" to another element, it can be directly connected or coupled to the other element or intervening elements may be present. In contrast, when an element is referred to as being "directly connected" or "directly coupled" to another element, there are no intervening elements present.

Relative terms such as "below" or "above" or "upper" or "lower" or "horizontal" or "vertical" may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms "a," "an," and "the" are intended to include the plural forms as well, unless the context clearly indicates otherwise. It will be further understood that the terms "comprises," "comprising," "includes," and/or "including" when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to improving voltage standing wave ratio (VSWR) immunity in a power management circuit. Herein, a power amplifier circuit includes an input hybrid coupler, a pair of power amplifiers, and an output hybrid coupler. The input hybrid coupler splits a radio frequency (RF) signal into an in-phase signal and a quadrature signal. One power amplifier is always active to amplify the quadrature signal based on a supply voltage, whereas another power amplifier is only active to amplify the in-phase signal based on the supply voltage when an instantaneous power level of the RF signal is above a first threshold. The output hybrid coupler combines the amplified quadrature signal and the amplified in-phase signal to thereby output the amplified RF signal. To help reduce a dynamic range of the supply voltage, the output hybrid coupler performs load modulation when the instantaneous power level of the RF signal is above the first threshold but below a second threshold and presents a fixed load impedance when the instantaneous power level is above the second threshold. In embodiments disclosed herein, the power amplifier circuit is configured to dynamically change a termination impedance of the output hybrid coupler based on the instantaneous power level and/or modulation bandwidth of the RF signal. As a result, it is possible to improve VSWR immunity (e.g., reduce reverse intermodulation) across a wide power range of the RF signal.

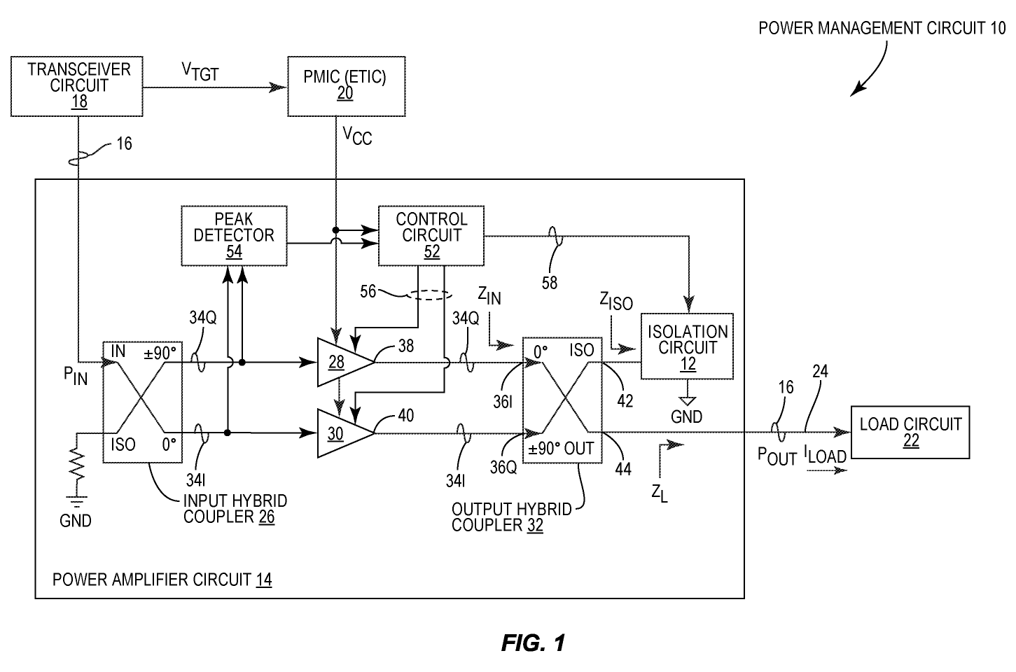

FIG. 1 is a schematic diagram of an exemplary power management circuit 10 wherein an isolation circuit 12 can be provided in a power amplifier circuit 14 and configured according to embodiments of the present disclosure to adapt a termination impedance Z_{ISO} based on an instantaneous power level and/or modulation bandwidth of an RF signal 16 being amplified by the power amplifier circuit 14 to help improve VSWR immunity of the power amplifier circuit 14.

The power management circuit 10 includes a transceiver circuit 18 and a power management integrated circuit (PMIC) 20. The transceiver circuit 18 is configured to generate the RF signal 16 having a time-variant input power P_{IN} and a target voltage V_{TGT} that tracks the time-variant input power P_{IN} of the RF signal 16. The PMIC 20 is configured to generate a supply voltage V_{CC} based on the target voltage V_{TGT}. In one embodiment, the PMIC 20 can generate the supply voltage V_{CC} as an envelope tracking (ET) voltage to track the time-variant input power P_{IN} of the RF signal 16. In another embodiment, the PMIC 20 can generate the supply voltage V_{CC} as an average power tracking (APT) voltage in accordance with an average of the time-variant input power P_{IN} of the RF signal 16. The power amplifier circuit 14 is configured to amplify the RF signal 16 from the time-variant input power P_{IN} to a time-variant output power P_{OUT} based on the supply voltage V_{CC} and provide the amplified RF signal 16 to a load circuit 22 (e.g., an RF frontend circuit) for transmission via a voltage path 24 (e.g., a conductive trace or a transmission line).

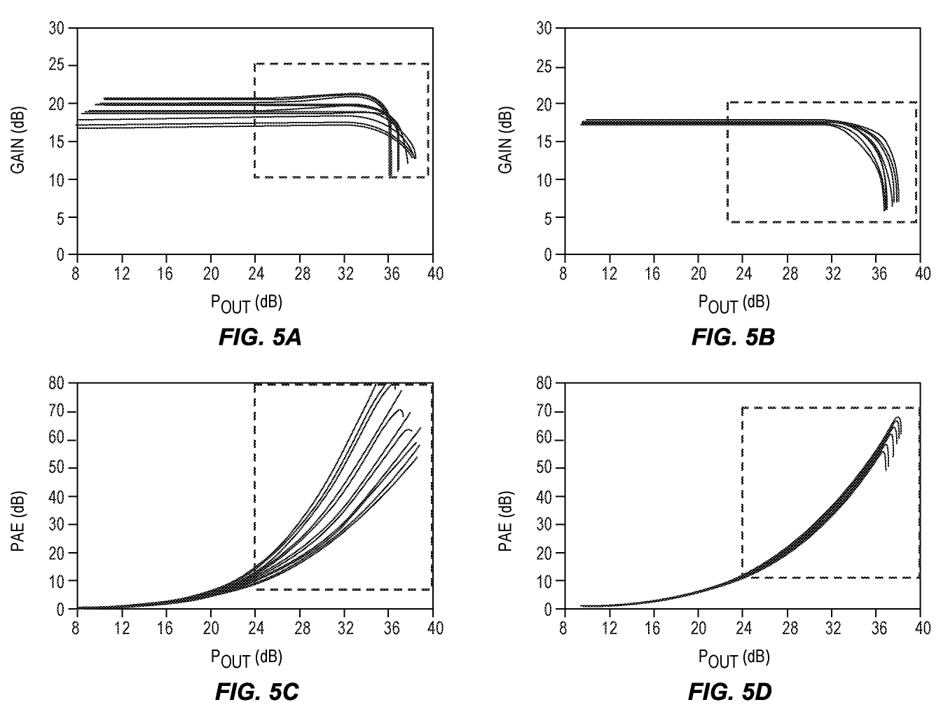

Notably, VSWR can be a ratio between a maximum and minimum level of the supply voltage V_{CC} in a standing wave pattern along the voltage path 24. In other words, VSWR is a measure of how well an impedance Z_{L} of the load circuit 22 matches the impedance of the voltage path 24. A lower VSWR is always desirable as it indicates a smaller reflection of the RF signal 16 and, thus, more power of the RF signal 16 is delivered to the load circuit 22. In context of the present disclosure, and as shown in FIGS. 5A-5D, VSWR immunity refers to a reduced spread in power amplifier gain and efficiency compared to an ideally matched power amplifier in response to load variations. In a specific non-limiting example, improving the VSWR immunity can further include a reduction of reverse intermodulation in the RF signal 16, particularly when the modulation bandwidth is below a bandwidth threshold (e.g., 100 MHz).

Specifically, the power amplifier circuit 14 includes an input hybrid coupler 26, a first power amplifier 28, a second power amplifier 30, and an output hybrid coupler 32. The input hybrid coupler 26 is configured to receive the RF signal 16 from the transceiver circuit 18 and split the RF signal 16 into an in-phase signal 34I and a quadrature signal 34Q. Each of the in-phase signal 34I and the quadrature signal 34Q will have one-half (½) of the time-variant input power P_{IN}. Herein, the quadrature signal 34Q has a +90° or -90° phase shift relative to the in-phase signal 34I.

In one embodiment, the first power amplifier 28 and the second power amplifier 30 can each be a differential power amplifier. Understandably, the first power amplifier 28 and the second power amplifier 30 may also be other types of power amplifiers. Understandably, each of the first power amplifier 28 and the second power amplifier 30 may include respective input and output matching circuits (not shown) to perform input and output impedance matching. Herein, the first power amplifier 28 is activated all the time to amplify the quadrature signal 34Q based on the supply voltage V_{CC}. In contrast, the second power amplifier 30 is only activated as needed to amplify the in-phase signal 34I.

The output hybrid coupler 32 includes an in-phase input 36I and a quadrature input 36Q. The in-phase input 36I is coupled to a first output 38 of the first power amplifier 28 to receive the amplified quadrature signal 34Q. The quadrature input 36Q is coupled to a second output 40 of the second power amplifier 30 to receive the amplified in-phase signal 34I when the second power amplifier 30 is activated. The output hybrid coupler 32 is configured herein to perform two functions. On one hand, the output hybrid coupler 32 combines the amplified quadrature signal 34Q with the amplified in-phase signal 34I to thereby output the amplified RF signal 16 at an output 44. On the other hand, the output hybrid coupler 32 is configured to modulate a load impedance Z_{IN} at the first output 38 of the first power amplifier 28 in accordance with the instantaneous power level of the RF signal 16, which can be the time-variant input power P_{IN} and/or the time-variant output power P_{OUT}.

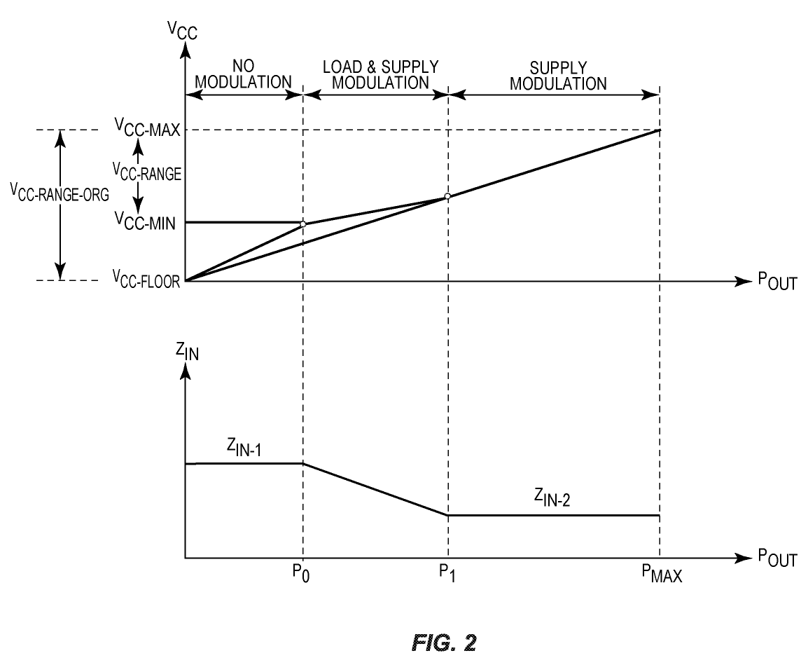

FIG. 2 is a graphic diagram providing an exemplary illustration as to how the PMIC 20 in FIG. 1 can adapt the supply voltage V_{CC} and how the output hybrid coupler 32 in FIG. 1 can modulate the load impedance Z_{IN} in accordance with the instantaneous power level of the RF signal 16. Common elements between FIGS. 1 and 2 are shown therein with common element numbers and will not be re-described herein.

In an embodiment, the output hybrid coupler 32 modulates the load impedance Z_{IN} based on a first power threshold P₀ and a second power threshold P₁. Herein, the second power threshold P₁ is approximately 8 to 10 dBs below a maximum power level P_{MAX} of the RF signal 16 and the first power threshold P₀ is approximately 4 to 6 dBs below the second power threshold P₁.

When the instantaneous power level of the RF signal 16 is lower than or equal to the first power threshold P₀, the output hybrid coupler 32 presents the load impedance Z_{IN} at a first fixed level Z_{IN-1}. When the instantaneous power level of the RF signal 16 is higher than the second power threshold P₁, the output hybrid coupler 32 presents the load impedance Z_{IN} at a second fixed level Z_{IN-2} (Z_{IN-2} < Z_{IN-1}). When the instantaneous power level of the RF signal 16 is higher than the first power threshold P₀ but lower than or equal to the second power threshold P₁, the output hybrid coupler 32 modulates the load impedance Z_{IN} in accordance with the instantaneous power level of the RF signal 16.

Concurrent to modulating the load impedance Z_{IN}, the PMIC 20 also adapts the supply voltage V_{CC} in accordance with the instantaneous power level of the RF signal 16. When the instantaneous power level of the RF signal 16 is lower than or equal to the first power threshold P₀, the PMIC 20 maintains the supply voltage V_{CC} constantly at a minimum voltage level V_{CC-MIN} independent of how the instantaneous power level of the RF signal 16 varies. Herein, the second power amplifier 30 is deactivated, whereas the first power amplifier 28 is activated to amplify the RF signal 16 (a.k.a. the quadrature signal 34Q) based on the supply voltage V_{CC}. As such, the power amplifier circuit 14 is said to operate without modulation.

When the instantaneous power level of the RF signal 16 is higher than the first power threshold P₀ but lower than or equal to the second power threshold P₁, the first power amplifier 28 will operate under full compression and the second power amplifier 30 will be activated. In the meantime, the PMIC 20 continues to generate the supply voltage V_{CC} based on the target voltage V_{TGT} to help drive up the time-variant output power P_{OUT}. Accordingly, the power amplifier circuit 14 is said to operate based on a combination of load modulation and supply modulation. As shown herein, the supply voltage V_{CC} is clipped at the first power threshold P₀ to thereby establish the minimum voltage level V_{CC-MIN}. Given that the minimum voltage level V_{CC-MIN} is higher than a voltage floor V_{CC-FLOOR}, it is thus possible to reduce the supply voltage V_{CC} from an original supply voltage range V_{CC-RANGE-ORG} (V_{CC-RANGE-ORG} = V_{CC-MAX} - V_{CC-FLOOR}) to a modified supply voltage range V_{CC-RANGE} (V_{CC-RANGE} = V_{CC-MAX} - V_{CC-MIN}).

When the instantaneous power level of the RF signal 16 becomes higher than the second power threshold P₁, the second power amplifier 30 will also operate under full compression. The PMIC 20 will once again generate the supply voltage V_{CC} in accordance with the instantaneous power of the RF signal 16 (a.k.a. the target voltage V_{TGT}). In this regard, the power amplifier circuit 14 will operate solely based on supply modulation. In the meantime, the first power amplifier 28 and the second power amplifier 30 will be biased equally to each deliver one-half (½) of the time-variant output power P_{OUT} and collectively drive the time-variant output power P_{OUT} toward the peak power level P_{MAX}.

In general, modulating the load impedance Z_{IN} can be performed by any passive impedance modulation circuits and the output hybrid coupler 32 is just one type of such passive impedance modulation circuits. For a more in-depth description and specific examples in terms of modulating the load impedance Z_{IN} using a passive impedance modulation circuit, please refer to PCT Patent Application Number PCT/US2025/033449, entitled “CONTROLLING A DUAL-AMPLIFIER POWER AMPLIFIER CIRCUIT IN A POWER MANAGEMENT CIRCUIT,” and PCT Patent Application Number PCT/US2025/041493, entitled “REDUCING SUPPLY VOLTAGE RANGE IN A POWER MANAGEMENT CIRCUIT.”

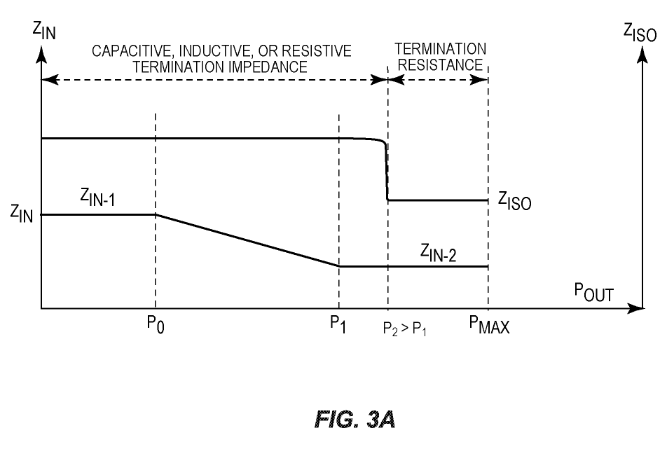

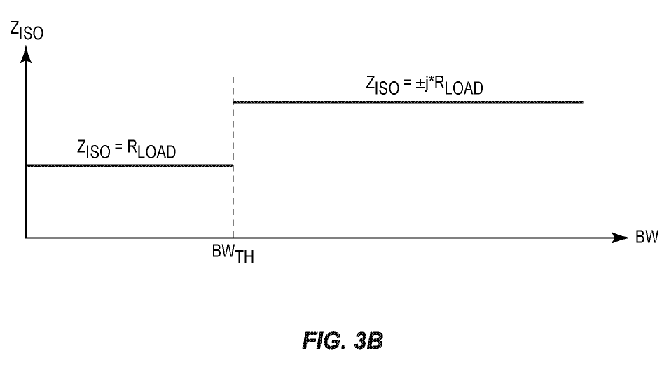

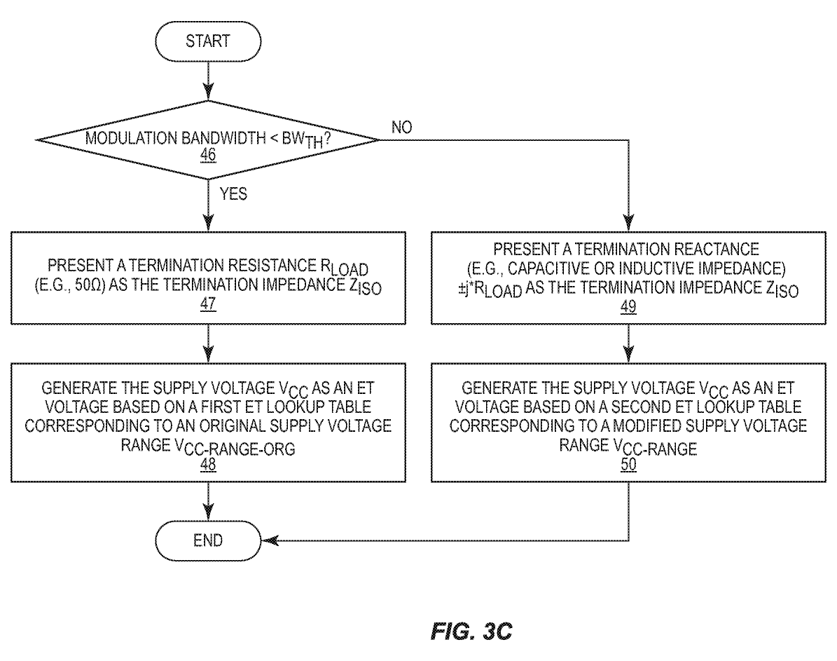

With reference back to FIG. 1, the output hybrid coupler 32 includes an isolation port 42 that is coupled to the isolation circuit 12. In one aspect, the isolation circuit 12 is configured to dynamically adapt the termination impedance Z_{ISO} at the isolation port 42 based on the instantaneous power level of the RF signal 16 to thereby help improve VSWR immunity of the power amplifier circuit 14. In this regard, FIG. 3A is a graphic diagram providing an exemplary illustration as to how the isolation circuit 12 in FIG. 1 can dynamically adapt the termination impedance Z_{ISO} based on the instantaneous power level of the RF signal 16 to help improve VSWR immunity of the power amplifier circuit 14. Common elements between FIGS. 1, 2, and 3A are shown therein with common element numbers and will not be re-described herein.

When the instantaneous power level of the RF signal 16 is lower than or equal to the second power threshold P₁, the isolation circuit 12 will present the termination impedance Z_{ISO} as a capacitive impedance, an inductive impedance, or a resistive impedance, depending on absolute phases of the in-phase input signal 34I and the quadrature input signal 34Q. By terminating the isolation port 42 with the capacitive impedance, the inductive impedance, or the resistive impedance, the output hybrid coupler 32 can thus modulate the load impedance Z_{IN} as described above in FIG. 2.

However, when the output hybrid coupler 32 is modulating the load impedance Z_{IN}, the time-variant output power P_{OUT} may be reflected from the load circuit 22. As a result, the power amplifier circuit 14 can suffer a worsening VSWR. Understandably from the previous discussion in FIG. 2, the output hybrid coupler 32 will modulate the load impedance Z_{IN} at the second fixed level Z_{IN-2} when the instantaneous power level of the RF signal 16 is higher than the second power threshold P₁. As such, in various embodiments, the isolation circuit 12 can be configured to change the termination impedance Z_{ISO} from the capacitive impedance, the inductive impedance, or the resistive impedance toward a termination resistance when the instantaneous power level of the RF signal 16 is higher than the second power threshold P₁.

In an embodiment, the isolation circuit 12 may be configured to transition from the capacitance impedance, the inductive impedance, or the resistive impedance toward the termination resistance when the instantaneous power level of the RF signal 16 is higher than the second power threshold P₁ but lower than or equal to a third power threshold P₂ that is approximately 0.5 to 1 dB higher than the second power threshold P₁. When the instantaneous power level of the RF signal 16 is higher than the third power threshold P₂, the isolation circuit 12 will only present the termination resistance at the isolation port 42 as the termination impedance Z_{ISO}. By presenting the termination impedance Z_{ISO} as the termination resistance, the reflected power of the RF signal 16 can be reflected at opposite phase angles to the first power amplifier 28 and the second power amplifier 30, thus helping to improve VSWR immunity of the power amplifier circuit 14.

With reference back to FIG. 1, in another aspect, the isolation circuit 12 can be configured to dynamically adapt the termination impedance Z_{ISO} at the isolation port 42 based on the modulation bandwidth of the RF signal 16 to thereby help reduce reverse intermodulation in the RF signal 16. In this regard, FIG. 3B is a graphic diagram illustrating how the isolation circuit 12 in FIG. 1 can dynamically adapt the termination impedance Z_{ISO} based on the modulation bandwidth of the RF signal 16. Common elements between FIGS. 1, 2 and 3B are shown therein with common element numbers and will not be re-described herein.

In an embodiment, the isolation circuit 12 can present a termination resistance R_{LOAD} (e.g., 50 Ω) as the termination impedance Z_{ISO} when the modulation bandwidth of the RF signal 16 is below a bandwidth threshold BW_{TH} (e.g., 100 MHz). By terminating the isolation port 42 by the termination resistance R_{LOAD}, the first power amplifier 28 and the second power amplifier 30 will be driven by the output hybrid coupler 32, in conjunction with the input hybrid coupler 26, to operate as a balanced power amplifier circuit. As a result, it is possible to improve impedance matching and minimize nonlinear distortion at the isolation port 42 to thereby reduce reverse intermodulation in the power amplifier circuit 14.

In contrast, when the modulation bandwidth of the RF signal 16 is higher than or equal to the bandwidth threshold BW_{TH}, the isolation circuit 12 will present a termination reactance (e.g., capacitive or inductive impedance) ±j*R_{LOAD} as the termination impedance Z_{ISO}. As a result, as previously described in FIG. 2, it is possible to reduce the supply voltage V_{CC} from the original supply voltage range V_{CC-RANGE-ORG} to the modified supply voltage range V_{CC-RANGE} to help improve efficiency of the PMIC 20 and allow the power amplifier circuit 14 to operate based at least on load modulation when the instantaneous power level of the RF signal 16 is higher than the first power threshold P₀ but lower than or equal to the second power threshold P₁.

Concurrent to adapting the termination impedance Z_{ISO} in accordance with the modulation bandwidth of the RF signal 16, the PMIC 20 can be configured to also adapt the supply voltage V_{CC} based on the modulation bandwidth of the RF signal 16. In this regard, FIG. 3C is a flowchart providing an exemplary illustration as to how the PMIC 20 in FIG. 1 can adapt the supply voltage V_{CC} based on the modulation bandwidth of the RF signal 16.

Herein, the PMIC 20 checks whether the modulation bandwidth of the RF signal 16 is lower than the bandwidth threshold BW_{TH} (step 46). In an embodiment, the PMIC 20 may receive an indication of the modulation bandwidth from the transceiver circuit 18. If the modulation bandwidth of the RF signal 16 is lower than the bandwidth threshold BW_{TH}, the isolation circuit 12 can present a termination resistance R_{LOAD} (e.g., 50 Ω) as the termination impedance Z_{ISO} (step 47). As such, the power amplifier circuit 14 can operate as the balanced power amplifier circuit. Accordingly, the PMIC 20 will generate the supply voltage V_{CC} as an ET voltage based on a first ET lookup table (not shown) that corresponds to the original supply voltage range V_{CC-RANGE-ORG} (step 48). If the modulation bandwidth of the RF signal 16 is higher than or equal to the bandwidth threshold BW_{TH}, the isolation circuit 12 will present the termination reactance (e.g., capacitive or inductive impedance) ±j*R_{LOAD} as the termination impedance Z_{ISO} (step 49). As such, the power amplifier circuit 14 can operate based on load modulation when the instantaneous power level of the RF signal 16 is higher than the first power threshold P₀ but lower than or equal to the second power threshold P1. Accordingly, the PMIC 20 will generate the supply voltage V_{CC} as the ET voltage based on a second ET lookup table (not shown) that corresponds to the modified supply voltage range V_{CC-RANGE} (step 50). In an embodiment, the first ET lookup table and the second ET lookup table can both be predetermined and stored in the PMIC 20.

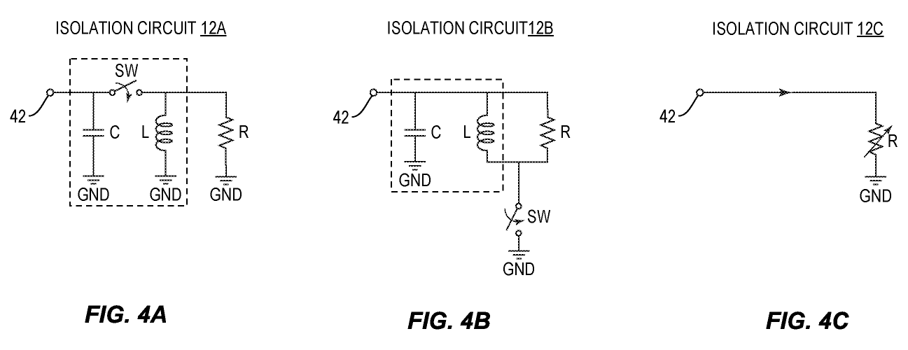

The isolation circuit 12 in FIG. 1 can be configured according to various embodiments. In this regard, FIGS. 4A-4C are schematic diagrams illustrating various configurations of the isolation circuit 12 in FIG. 1. Common elements between FIGS. 1 and 4A-4C are shown therein with common element numbers and will not be re-described herein.

FIG. 4A is a schematic diagram illustrating an isolation circuit 12A configured according to a first embodiment of the present disclosure. Herein, the isolation circuit 12A includes a capacitor C, an inductor L, and a resistor R that are coupled in parallel between the isolation port 42 and a ground (GND). The isolation circuit 12A also includes a switch SW that is also coupled to the isolation port 42. More specifically, the switch SW is provided in between the capacitor C and the inductor L.

When the instantaneous power level of the RF signal 16 is higher than the third power threshold P₂, the switch SW is closed. As a result, a capacitive impedance of the capacitor C will be offset by an inductive impedance of the inductor L, leaving behind a resistive impedance provided by the resistor R. When the instantaneous power level of the RF signal 16 is lower than or equal to the third power threshold P₂, the switch SW will be opened. As a result, the isolation circuit 12A presents the capacitive impedance of the capacitor C at the isolation port 42.

FIG. 4B is a schematic diagram illustrating an isolation circuit 12B configured according to a second embodiment of the present disclosure. Herein, the isolation circuit 12B includes a capacitor C, an inductor L, and a resistor R. The capacitor C is coupled between the isolation port 42 and the GND. The resistor R and the inductor L are coupled in parallel between the isolation port 42 and a switch SW, which is further coupled to the GND.

When the instantaneous power level of the RF signal 16 is higher than the third power threshold P₂, the switch SW is closed. As a result, a capacitive impedance of the capacitor C will be offset by an inductive impedance of the inductor L, leaving behind a resistive impedance provided by the resistor R. When the instantaneous power level of the RF signal 16 is lower than or equal to the third power threshold P₂, the switch SW will be opened.

FIG. 4C is a schematic diagram illustrating an isolation circuit 12C configured according to a second embodiment of the present disclosure. Herein, the isolation circuit 12C includes a variable resistor R that is coupled between the isolation port 42 and the GND. When the instantaneous power level of the RF signal 16 is higher than the third power threshold P₂, the variable resistor R is configured to present a resistance that matches the impedance of the output hybrid coupler 32. When the instantaneous power level of the RF signal 16 is lower than or equal to the third power threshold P₂, the variable resistor R is adjusted to a high or low value relative to the impedance of the output hybrid coupler 32.

With reference back to FIG. 1, the power amplifier circuit 14 further includes a control circuit 52 and a peak detector 54. The peak detector 54 is configured to detect the instantaneous power level of the RF signal 16 based on both the in-phase signal 34I and the quadrature signal 34Q. By detecting the instantaneous power level of the RF signal 16 based on both the in-phase signal 34I and the quadrature signal 34Q, the peak detector 54 can effectively double samples of the RF signal 16 without increasing a sampling rate, thus allowing the peak detector 54 to operate with improved RF filtering and over a wider bandwidth with less group delay. In an embodiment, the peak detector 54 can be an automatic gain control (AGC) configured to operate based on an expected average input power level for different power backoffs.

In an embodiment, the control circuit 52 receives the supply voltage V_{CC} from the PMIC 20. The control circuit 52 also receives the detected instantaneous power level of the RF signal 16 from the peak detector 54. Accordingly, the control circuit 52 can bias the first power amplifier 28 and/or the second power amplifier 30 via a bias signal 56. As an example, the control circuit 52 can use the bias signal 56 to activate or deactivate the second power amplifier 30 as needed. The control circuit 52 is further configured to control the switch SW in the isolation circuit 12A of FIG. 4A, the isolation circuit 12B of FIG. 4B or adjust the variable resistor R in the isolation circuit 12C of FIG. 4C via a switching signal 58 in accordance with the instantaneous power level and/or the modulation bandwidth of the RF signal 16.

In an embodiment, the RF signal 16 may be modulated into multiple orthogonal frequency division multiplexing (OFDM) symbols that are logically organized into multiple slots or mini slots. As such, in one embodiment, the control circuit 52 may be configured to adapt the termination impedance Z_{ISO} on a per-symbol basis. In another embodiment, the control circuit 52 may also be configured to adapt the termination impedance Z_{ISO} on a per-slot or per-mini slot basis. In an embodiment, the transceiver circuit 18 may indicate the modulation bandwidth of the RF signal 16 to the control circuit 52 via, for example, an RF frontend (RFFE) interface. Alternatively, the control circuit 52 may self-determine the modulation bandwidth of the RF signal 16 based on, for example, the number of resource blocks that are assigned to carry the RF signal 16.

FIGS. 5A-5D are graphic diagrams providing exemplary illustrations of VSWR immunity improvement achieved by the power amplifier circuit 14 in the power management circuit 10 of FIG. 1. Specifically, FIG. 5A illustrates gain variation of a conventional power amplifier without the input hybrid coupler 26 and the output hybrid coupler 32, FIG. 5B illustrates the gain variation of the power amplifier circuit 14 in FIG. 1 configured according to embodiments described above, FIG. 5C illustrates a power amplifier efficiency (PAE) variation of the conventional power amplifier, and FIG. 5D illustrates a PAE variation of the power amplifier circuit 14.

As an example, when the time-variant output power P_{OUT} is between 24 dB and 40 dB, the gain variation of the ideally matched power amplifier, as shown in FIG. 5A, has a wider spread than that of the power amplifier circuit 14 as shown in FIG. 5B. Similarly, the PAE variation of the ideally matched power amplifier, as shown in FIG. 5C, also has a much wider spread than that of the power amplifier circuit 14 as shown in FIG. 5D. The obvious tightening of the gain variation and the PAE variation indicates that the power amplifier circuit 14 has achieved an improved VSWR immunity compared to the ideally matched power amplifier.

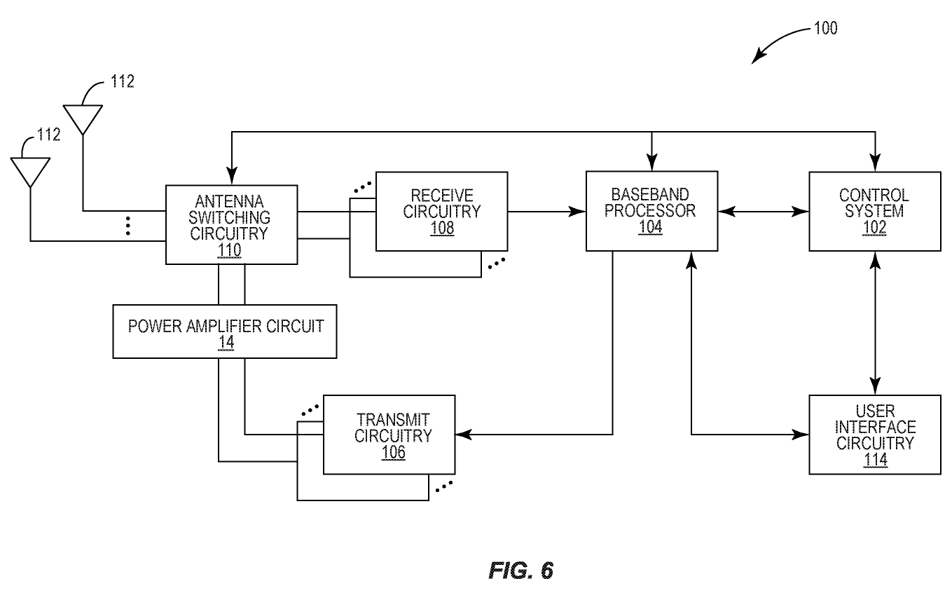

The power management circuit 10 of FIG. 1 can be provided in a communication device to support the embodiments described above. In this regard, FIG. 6 is a schematic diagram of an exemplary communication device 100 wherein the power management circuit 10 of FIG. 1 can be provided.

Herein, the communication device 100 can be any type of communication devices, such as mobile terminals, smart watches, tablets, computers, navigation devices, access points, base stations (e.g., eNB, gNB, etc.), and like wireless communication devices that support wireless communications, such as cellular, wireless local area network (WLAN), Ultra-wideband (UWB), Bluetooth, and near-field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor, an embedded memory circuit, and a communication bus interface. The receive circuitry 108 receives radio frequency signals via the antennas 112 and through the antenna switching circuitry 110 from one or more base stations. A low-noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converters (ADCs).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application-specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 112 through the antenna switching circuitry 110. The multiple antennas 112 and the replicated transmit 106 and receive circuitry 108 may provide spatial diversity. Modulation and processing details will be understood by those skilled in the art.

In an embodiment, the transmit circuitry 106 and the receive circuitry 108 can function as the transceiver circuit 18 in FIG. 1. Accordingly, the power amplifier circuit 14 can be provided between the transmit circuitry 106 and the antenna switching circuitry 110.

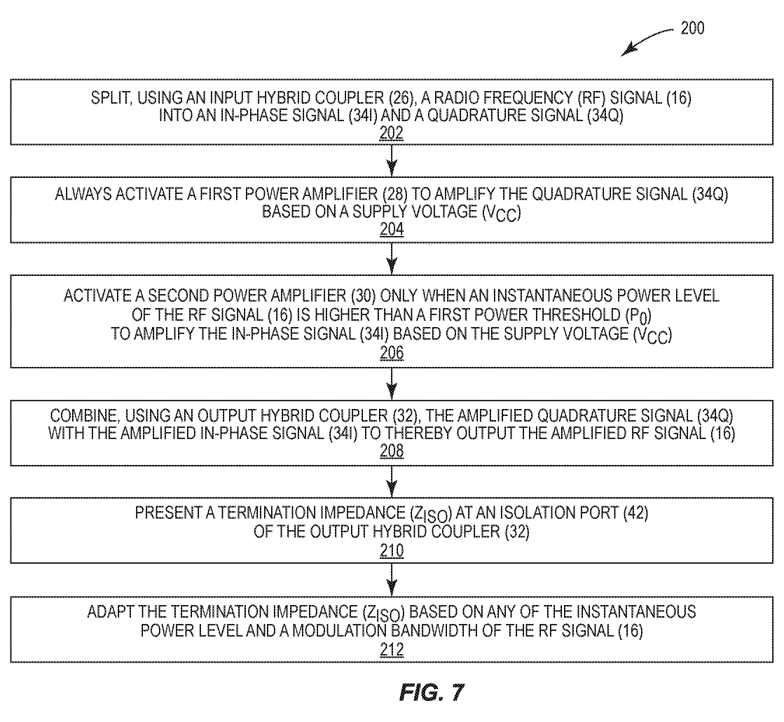

In an embodiment, the power management circuit 10 of FIG. 1 can be configured to improve VSWR immunity in accordance with a process. In this regard, FIG. 7 is a flowchart of an exemplary process 200 for improving the VSWR immunity in the power management circuit 10 of FIG. 1.

Herein, the process 200 includes splitting, using the input hybrid coupler 26, the RF signal 16 into the in-phase signal 34I and the quadrature signal 34Q (step 202). The process 200 also includes always activating the first power amplifier 28 to amplify the quadrature signal 34Q based on the supply voltage V_{CC} (step 204). The process 200 also includes activating the second power amplifier 30 only when the instantaneous power level of the RF signal 16 is higher than the first power threshold P₀ to amplify the in-phase signal 34I based on the supply voltage V_{CC} (step 206). The process 200 also includes combining, using the output hybrid coupler 32, the amplified quadrature signal 34Q with the amplified in-phase signal 34I to thereby output the amplified RF signal 16 (step 208). The process 200 also includes presenting the termination impedance Z_{ISO} at the isolation port 42 of the output hybrid coupler 32 (step 210). The process 200 also includes adapting the termination impedance Z_{ISO} based on any of the instantaneous power level and a modulation bandwidth of the RF signal 16 (step 212).

Those skilled in the art will recognize improvements and modifications to the preferred embodiments of the present disclosure. All such improvements and modifications are considered within the scope of the concepts disclosed herein and the claims that follow.

What is claimed is:

1. A power management circuit comprising a power amplifier circuit, the power amplifier circuit comprises:
an input hybrid coupler configured to split a radio frequency (RF) signal into an in-phase signal and a quadrature signal;
a first power amplifier always activated to amplify the quadrature signal based on a supply voltage;
a second power amplifier activated only when an instantaneous power level of the RF signal is higher than a first power threshold to amplify the in-phase signal based on the supply voltage;
an output hybrid coupler having an isolation port terminated by a termination impedance and configured to output the amplified RF signal based on the amplified quadrature signal and the amplified in-phase signal;
an isolation circuit coupled to the isolation port and configured to present the termination impedance at the isolation port; and
a control circuit configured to control the isolation circuit to adapt the termination impedance based on any of the instantaneous power level and a modulation bandwidth of the RF signal.

2. The power management circuit of claim 1, wherein the control circuit is further configured to:
control the isolation circuit to present the termination impedance as one of a capacitive impedance, an inductive impedance, and a resistive impedance when the instantaneous power level of the RF signal is lower than or equal to a second power threshold higher than the first power threshold;
control the isolation circuit to transition from the termination impedance toward a termination resistance when the instantaneous power level of the RF signal is higher than the second power threshold but lower than or equal to a third power threshold higher than the second power threshold; and
control the isolation circuit to present the termination impedance as the termination resistance when the instantaneous power level of the RF signal is higher than the third power threshold.

3. The power management circuit of claim 2, wherein the isolation circuit comprises:
a capacitor, an inductor, and a resistor coupled in parallel between the isolation port and a ground; and
a switch coupled to the isolation port and provided in between the capacitor and the inductor;
wherein the control circuit is further configured to:
close the switch when the instantaneous power level of the RF signal is higher than the third power threshold; and
open the switch when the instantaneous power level of the RF signal is lower than the third power threshold.

4. The power management circuit of claim 2, wherein the isolation circuit comprises:
a capacitor coupled between the isolation port and a ground;
an inductor and a resistor coupled in parallel between the isolation port and a switch that is further coupled to the ground;
wherein the control circuit is further configured to:
close the switch when the instantaneous power level of the RF signal is higher than or equal to the third power threshold; and
open the switch when the instantaneous power level of the RF signal is lower than the third power threshold.

5. The power management circuit of claim 2, wherein the isolation circuit comprises:
a variable resistor coupled in series between the isolation port and a ground;
wherein the control circuit is further configured to:
adjust the variable resistor to match an impedance of the output hybrid coupler when the instantaneous power level of the RF signal is higher than or equal to the third power threshold; and
adjust the variable resistor to be higher than or lower than the impedance of the output hybrid coupler when the instantaneous power level of the RF signal is lower than the third power threshold.

6. The power management circuit of claim 1, wherein the control circuit is further configured to:
control the isolation circuit to present the termination impedance as a termination resistance when the modulation bandwidth of the RF signal is lower than a bandwidth threshold; and
control the isolation circuit to present the termination impedance as a termination reactance when the modulation bandwidth of the RF signal is higher than or equal to the bandwidth threshold.

7. The power management circuit of claim 6, wherein the isolation circuit comprises:
a capacitor, an inductor, and a resistor coupled in parallel between the isolation port and a ground; and
a switch coupled to the isolation port and provided in between the capacitor and the inductor;
wherein the control circuit is further configured to:
close the switch when the modulation bandwidth of the RF signal is lower than the bandwidth threshold to thereby present the termination resistance as the termination impedance; and
open the switch when the modulation bandwidth of the RF signal is higher than or equal to the bandwidth threshold to thereby present the termination reactance as the termination impedance.

8. The power management circuit of claim 6, wherein the isolation circuit comprises:
a capacitor coupled between the isolation port and a ground; and
an inductor and a resistor coupled in parallel between the isolation port and a switch that is further coupled to the ground;
wherein the control circuit is further configured to:
close the switch when the modulation bandwidth of the RF signal is lower than the bandwidth threshold to thereby present the termination resistance as the termination impedance; and
open the switch when the modulation bandwidth of the RF signal is higher than or equal to the bandwidth threshold to thereby present the termination reactance as the termination impedance.

9. The power management circuit of claim 1, wherein the output hybrid coupler is further configured to:
maintain a load impedance at an output of the first power amplifier at a first fixed level when the instantaneous power level of the RF signal is lower than or equal to the first power threshold;
modulate the load impedance when the instantaneous power level of the RF signal is higher than the first power threshold but lower than or equal to a second power threshold; and
maintain the load impedance at a second fixed level lower than the first fixed level when the instantaneous power level of the RF signal is higher than the second power threshold.

10. The power management circuit of claim 9, further comprising:
a transceiver circuit configured to:
generate the RF signal and a target voltage tracking the instantaneous power level of the RF signal; and
indicate the modulation bandwidth of the RF signal to the control circuit; and
a power management integrated circuit (PMIC) configured to:
maintain the supply voltage at a minimum voltage level higher than a voltage floor independent of the instantaneous power level of the RF signal; and
generate the supply voltage based on the target voltage when the instantaneous power level of the RF signal is higher than the first power threshold.

11. The power management circuit of claim 10, wherein the PMIC is further configured to:
generate the supply voltage based on a first envelope tracking (ET) lookup table corresponding to an original supply voltage range defined by a maximum voltage level and the voltage floor when the modulation bandwidth of the RF signal is lower than a bandwidth threshold; and
generate the supply voltage based on a second ET lookup table corresponding to a modified supply voltage range defined by the maximum voltage level and the minimum voltage level when the modulation bandwidth of the RF signal is higher than or equal to the bandwidth threshold.

12. A wireless device comprising a power management circuit, the power management circuit comprises a power amplifier circuit that comprises:
an input hybrid coupler configured to split a radio frequency (RF) signal into an in-phase signal and a quadrature signal;
a first power amplifier always activated to amplify the quadrature signal based on a supply voltage;
a second power amplifier activated only when an instantaneous power level of the RF signal is higher than a first power threshold to amplify the in-phase signal based on the supply voltage;
an output hybrid coupler having an isolation port terminated by a termination impedance and configured to output the amplified RF signal based on the amplified quadrature signal and the amplified in-phase signal;
an isolation circuit coupled to the isolation port and configured to present the termination impedance; and
a control circuit configured to control the isolation circuit to adapt the termination impedance based on any of the instantaneous power level and a modulation bandwidth of the RF signal.

13. The wireless device of claim 12, wherein the control circuit is further configured to:
control the isolation circuit to present the termination impedance as one of a capacitive impedance, an inductive impedance, and a resistive impedance when the instantaneous power level of the RF signal is lower than or equal to a second power threshold higher than the first power threshold;
control the isolation circuit to transition from the termination impedance toward a termination resistance when the instantaneous power level of the RF signal is higher than the second power threshold but lower than or equal to a third power threshold higher than the second power threshold; and
control the isolation circuit to present the termination impedance as the termination resistance when the instantaneous power level of the RF signal is higher than or equal to the third power threshold.

14. The wireless device of claim 12, wherein the control circuit is further configured to:
control the isolation circuit to present the termination impedance as a termination resistance when the modulation bandwidth of the RF signal is lower than a bandwidth threshold; and
control the isolation circuit to present the termination impedance as a termination reactance when the modulation bandwidth of the RF signal is higher than or equal to the bandwidth threshold.

15. The wireless device of claim 12, wherein the power management circuit further comprises:
a transceiver circuit configured to:
generate the RF signal and a target voltage tracking the instantaneous power level of the RF signal; and
indicate the modulation bandwidth of the RF signal to the control circuit; and
a power management integrated circuit (PMIC) configured to:
maintain the supply voltage at a minimum voltage level higher than a voltage floor independent of the instantaneous power level of the RF signal; and
generate the supply voltage based on the target voltage when the instantaneous power level of the RF signal is higher than the first power threshold.

16. The wireless device of claim 15, wherein the PMIC is further configured to:
generate the supply voltage based on a first envelope tracking (ET) lookup table corresponding to an original supply voltage range defined by a maximum voltage level and the voltage floor when the modulation bandwidth of the RF signal is lower than a bandwidth threshold; and
generate the supply voltage based on a second ET lookup table corresponding to a modified supply voltage range defined by the maximum voltage level and the minimum voltage level when the modulation bandwidth of the RF signal is higher than or equal to the bandwidth threshold.

17. A method for improving voltage standing wave ratio (VSWR) immunity in a power management circuit comprising:
splitting, using an input hybrid coupler, a radio frequency (RF) signal into an in-phase signal and a quadrature signal;
always activating a first power amplifier to amplify the quadrature signal based on a supply voltage;
activating a second power amplifier only when an instantaneous power level of the RF signal is higher than a first power threshold to amplify the in-phase signal based on the supply voltage;
combining, using an output hybrid coupler, the amplified quadrature signal with the amplified in-phase signal to thereby output the amplified RF signal;
presenting a termination impedance at an isolation port of the output hybrid coupler; and
adapting the termination impedance based on any of the instantaneous power level and a modulation bandwidth of the RF signal.

18. The method of claim 17, further comprising:
presenting the termination impedance as one of a capacitive impedance, an inductive impedance, and a resistive impedance when the instantaneous power level of the RF signal is lower than or equal to a second power threshold higher than the first power threshold;
transitioning from the termination impedance toward a termination resistance when the instantaneous power level of the RF signal is higher than the second power threshold but lower than or equal to a third power threshold higher than the second power threshold; and
presenting the termination impedance as the termination resistance when the instantaneous power level of the RF signal is higher than the third power threshold.

19. The method of claim 17, further comprising:
presenting the termination impedance as a termination resistance when the modulation bandwidth of the RF signal is lower than a bandwidth threshold; and
presenting the termination impedance as a termination reactance when the modulation bandwidth of the RF signal is higher than or equal to the bandwidth threshold.

20. The method of claim 19, further comprising:
generating the supply voltage based on a first envelope tracking (ET) lookup table corresponding to an original supply voltage range defined by a maximum voltage level and a voltage floor when the modulation bandwidth of the RF signal is lower than the bandwidth threshold; and
generate the supply voltage based on a second ET lookup table corresponding to a modified supply voltage range defined by the maximum voltage level and a minimum voltage level higher than the voltage floor when the modulation bandwidth of the RF signal is higher than or equal to the bandwidth threshold.

21. A power management circuit comprising a power amplifier circuit, the power amplifier circuit comprises:
an input hybrid coupler configured to split a radio frequency (RF) signal into an in-phase signal and a quadrature signal;
a first power amplifier always activated to amplify the quadrature signal based on a supply voltage;
a second power amplifier activated only when an instantaneous power level of the RF signal is higher than a first power threshold to amplify the in-phase signal based on the supply voltage;
an output hybrid coupler having an isolation port terminated by a termination impedance and configured to output the amplified RF signal based on the amplified quadrature signal and the amplified in-phase signal; and
a control circuit configured to:
cause a termination resistance to be presented at the isolation port when the modulation bandwidth of the RF signal is lower than a bandwidth threshold such that the power amplifier circuit can operate as a balanced power amplifier circuit; and
cause a termination reactance to be presented at the isolation port when the modulation bandwidth of the RF signal is higher than or equal to the bandwidth threshold such that the power amplifier circuit can operate based at least on load modulation.
